(19) United States
(12) Patent Application Publication
(10) Pub. No.: US 2026/0261191 A1
(43) Pub. Date: Sep. 3, 2026

(54) SUPERCONDUCTIVE MAGNET ASSEMBLY, PLANAR MOTOR AND LITHOGRAPHIC APPARATUS

(71) Applicant: ASML Netherlands B.V., Veldhoven (NL)

(72) Inventors: Roger Franciscus Mattheus Maria HAMELINCK, Breda (NO); Gudrun Ghilaine Agnes DE GERSEM, Veldhoven (NL); Jeroen VAN DUIVENBODE, Veldhoven (NL); Emiel Anton VAN DE VAN, Delft (NL); Rien Johan Hein WESSELINK, Enschede (NL)

(73) Assignee: ASML Netherlands B.V., Veldhoven (NL)

(21) Appl. No.: 18/875,996

(22) PCT Filed: Jul. 26, 2023
(86) PCT No.: PCT/EP2023/070786

§ 371 Date: Dec. 17, 2024

(30) Foreign Application Priority Data
Aug. 18, 2022 (EP) 22191098.7

(51) Int. Cl. H02K 55/02; G03F 7/00

(52) U.S. Cl. CPC H02K 55/02; G03F 7/70758; G03F 7/70858; G03F 7/70991

(57) ABSTRACT

There is provided a superconductive (SC) magnet assembly for a planar motor that includes one or more of the following elements. A two-dimensional (2D) array of SC coils configured to generate a two-dimensional spatially alternating magnetic field. A shield arranged on a side of the 2D array of SC coils facing, during use, a mover of the planar motor, the shield being configured to mitigate a magnetic field change as experienced by the 2D array of SC coils. The shield comprises a layer of conductive material, the layer spanning an area substantially covering the 2D array of SC coils, the layer of conductive material having a thickness variation across the area, the thickness variation across the area being associated with a magnetic pitch of the array of SC coils, an inner diameter of a coil of the array of SC coils or an outer diameter of a coil of the array of SC coils of the 2D array of SC coils.

### CROSS-REFERENCE TO RELATED APPLICATIONS

This application claims priority of EP application 22191098.7 which was filed on Aug. 18, 2022 and which is incorporated herein in its entirety by reference.

### FIELD

The present invention relates to a superconductive magnet assembly for a planar motor, a planar motor and a lithographic apparatus comprising such a planar motor.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) of a patterning device (e.g., a mask) onto a layer of radiation-sensitive material (resist) provided on a substrate (e.g., a wafer).

As semiconductor manufacturing processes continue to advance, the dimensions of circuit elements have continually been reduced while the amount of functional elements, such as transistors, per device has been steadily increasing over decades, following a trend commonly referred to as ‘Moore's law’. To keep up with Moore's law the semiconductor industry is chasing technologies that enable to create increasingly smaller features. To project a pattern on a substrate a lithographic apparatus may use electromagnetic radiation. The wavelength of this radiation determines the minimum size of features which are patterned on the substrate. Typical wavelengths currently in use are 365 nm (i-line), 248 nm, 193 nm and 13.5 nm. A lithographic apparatus, which uses extreme ultraviolet (EUV) radiation, having a wavelength within a range of 4 nm to 20 nm, for example 6.7 nm or 13.5 nm, may be used to form smaller features on a substrate than a lithographic apparatus which uses, for example, radiation with a wavelength of 193 nm.

In general, there is an aim to increase the productivity and accuracy of apparatuses such as lithographic apparatuses. To increase the productivity of a lithographic apparatus, more powerful motors may be applied to position the substrate and the patterning device. An example of such a motor is a superconductive planar motor. Superconductive motors apply superconductive coils to generate a magnetic field. The magnetic field strength that can be realised is typically much higher than a magnetic field strength of a conventional planar motor which e.g. applies permanent magnets. In order to generate the magnetic field, it is important that the superconductive coils as applied maintain, during operation, in the superconductive state. It has been observed that, in known arrangement, there may be risk of the coils losing their superconductive state, due to losses induced in the coils.

### SUMMARY

It is an objective of the present invention to provide a superconductive magnet assembly for a planar motor whereby a superconductive state of the coils of the assembly is more easily maintained.

According to an aspect of the invention, there is provided a superconductive (SC) magnet assembly for a planar motor, the superconductive magnet assembly comprising:
a two-dimensional (2D) array of SC coils configured to generate a two-dimensional spatially alternating magnetic field;
a shield arranged on a side of the 2D array of SC coils facing, during use, a mover of the planar motor, the shield being configured to mitigate a magnetic field change as experienced by the 2D array of SC coils;
   wherein the shield comprises a layer of conductive material, the layer spanning an area substantially covering the 2D array of SC coils, the layer of conductive material having a thickness variation across the area, the thickness variation across the area being associated with a geometric parameter of the 2D array of SC coils.

According to another aspect of the invention, there is provided a planar motor for use in a lithographic apparatus, the planar motor comprising a superconductive magnet assembly according to the invention.

According to another aspect of the invention, there is provided a lithographic apparatus, the lithographic apparatus comprising a planar motor according to the invention for displacing a substrate.

### BRIEF DESCRIPTION OF THE DRAWINGS

Embodiments of the invention will now be described, by way of example only, with reference to the accompanying schematic drawings, in which:

FIG. 1 depicts a schematic overview of a lithographic apparatus according to the invention;

FIG. 2 depicts a detailed view of a part of the lithographic apparatus of FIG. 1;

FIG. 3 schematically depicts a position control system;

FIG. 4 depicts a top view of a planar motor with a magnet assembly comprising permanent magnets;

FIG. 5 depicts a top view of a 2D array of SC coils;

FIG. 6 depicts a top view of a planar motor with a magnet assembly comprising a 2D array of SC coils;

FIG. 7 depicts a side view of the planar motor of FIG. 6;

FIG. 8 depicts a side view of a planar motor according to the invention;

FIG. 9 depicts a first example of a layer of conductive material as can be applied as a shield in the present invention;

FIGS. 10a-10c depict further examples of layers of conductive material as can be applied as a shield in the present invention.

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

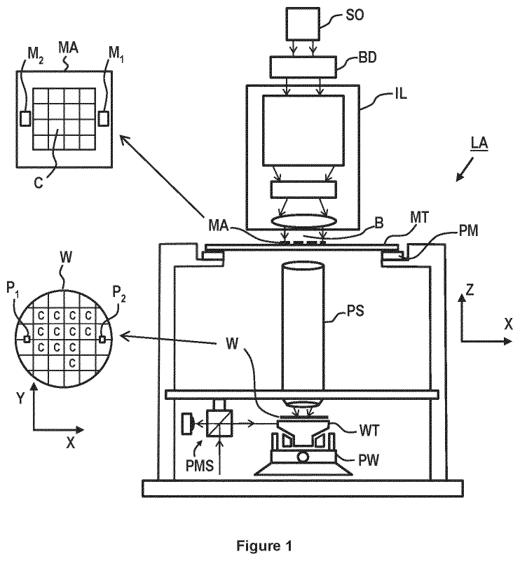

FIG. 1 schematically depicts a lithographic apparatus LA. The lithographic apparatus LA includes an illumination system (also referred to as illuminator) IL configured to condition a radiation beam B (e.g., UV radiation, DUV radiation or EUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a wafer table) WT constructed to hold a substrate (e.g., a resist coated wafer) W and connected to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W. In an embodiment, the second positioner PW can e.g. comprise a planar motor according to the present invention.

In operation, the illumination system IL receives a radiation beam from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus LA may be of a type wherein at least a portion of the substrate may be covered by a liquid having a relatively high refractive index, e.g., water, so as to fill a space between the projection system PS and the substrate W-which is also referred to as immersion lithography. More information on immersion techniques is given in U.S. Pat. No. 6,952,253, which is incorporated herein by reference.

The lithographic apparatus LA may also be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus LA may comprise a measurement stage. The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support MT, and is patterned by the pattern (design layout) present on patterning device MA. Having traversed the patterning device MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

To clarify the invention, a Cartesian coordinate system is used. The Cartesian coordinate system has three axis, i.e., an x-axis, a y-axis and a z-axis. Each of the three axis is orthogonal to the other two axis. A rotation around the x-axis is referred to as an Rx-rotation. A rotation around the y-axis is referred to as an Ry-rotation. A rotation around about the z-axis is referred to as an Rz-rotation. The x-axis and the y-axis define a horizontal plane, whereas the z-axis is in a vertical direction. The Cartesian coordinate system is not limiting the invention and is used for clarification only. Instead, another coordinate system, such as a cylindrical coordinate system, may be used to clarify the invention. The orientation of the Cartesian coordinate system may be different, for example, such that the z-axis has a component along the horizontal plane.

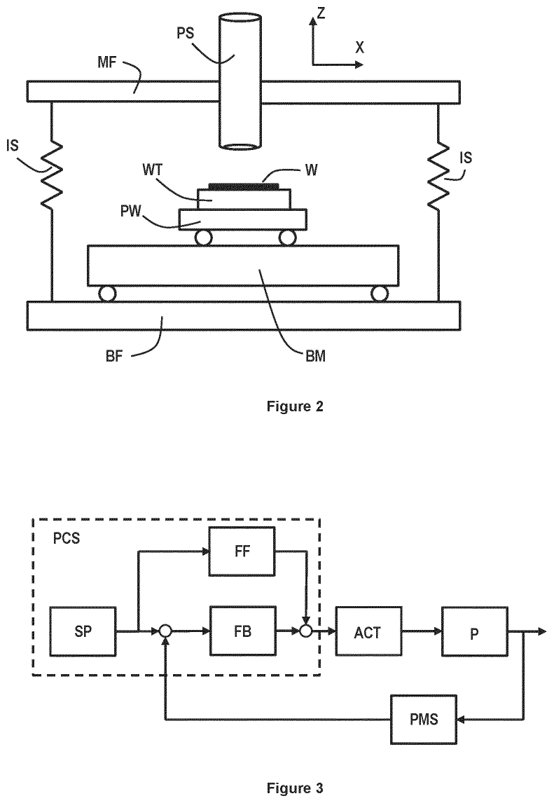

FIG. 2 shows a more detailed view of a part of the lithographic apparatus LA of FIG. 1. The lithographic apparatus LA may be provided with a base frame BF, a balance mass BM, a metrology frame MF and a vibration isolation system IS. The metrology frame MF supports the projection system PS. Additionally, the metrology frame MF may support a part of the position measurement system PMS. The metrology frame MF is supported by the base frame BF via the vibration isolation system IS. The vibration isolation system IS is arranged to prevent or reduce vibrations from propagating from the base frame BF to the metrology frame MF.

The second positioner PW is arranged to accelerate the substrate support WT by providing a driving force between the substrate support WT and the balance mass BM. The driving force accelerates the substrate support WT in a desired direction. Due to the conservation of momentum, the driving force is also applied to the balance mass BM with equal magnitude, but at a direction opposite to the desired direction. Typically, the mass of the balance mass BM is significantly larger than the masses of the moving part of the second positioner PW and the substrate support WT.

In an embodiment, the second positioner PW is supported by the balance mass BM. For example, wherein the second positioner PW comprises a planar motor to levitate the substrate support WT above the balance mass BM. In another embodiment, the second positioner PW is supported by the base frame BF. For example, wherein the second positioner PW comprises a linear motor and wherein the second positioner PW comprises a bearing, like a gas bearing, to levitate the substrate support WT above the base frame BF.

The position measurement system PMS may comprise any type of sensor that is suitable to determine a position of the substrate support WT. The position measurement system PMS may comprise any type of sensor that is suitable to determine a position of the mask support MT. The sensor may be an optical sensor such as an interferometer or an encoder. The position measurement system PMS may comprise a combined system of an interferometer and an encoder. The sensor may be another type of sensor, such as a magnetic sensor, a capacitive sensor or an inductive sensor. The position measurement system PMS may determine the position relative to a reference, for example the metrology frame MF or the projection system PS. The position measurement system PMS may determine the position of the substrate table WT and/or the mask support MT by measuring the position or by measuring a time derivative of the position, such as velocity or acceleration.

The position measurement system PMS may comprise an encoder system. An encoder system is known from for example, United States patent application US2007/0058173A1, filed on Sep. 7, 2006, hereby incorporated by reference. The encoder system comprises an encoder head, a grating and a sensor. The encoder system may receive a primary radiation beam and a secondary radiation beam. Both the primary radiation beam as well as the secondary radiation beam originate from the same radiation beam, i.e., the original radiation beam. At least one of the primary radiation beam and the secondary radiation beam is created by diffracting the original radiation beam with the grating. If both the primary radiation beam and the secondary radiation beam are created by diffracting the original radiation beam with the grating, the primary radiation beam needs to have a different diffraction order than the secondary radiation beam. Different diffraction orders are, for example, +1^{st} order, −1^{st} order, +2^{nd} order and −2^{nd} order. The encoder system optically combines the primary radiation beam and the secondary radiation beam into a combined radiation beam. A sensor in the encoder head determines a phase or phase difference of the combined radiation beam. The sensor generates a signal based on the phase or phase difference. The signal is representative of a position of the encoder head relative to the grating. One of the encoder head and the grating may be arranged on the substrate structure WT. The other of the encoder head and the grating may be arranged on the metrology frame MF or the base frame BF. For example, a plurality of encoder heads are arranged on the metrology frame MF, whereas a grating is arranged on a top surface of the substrate support WT. In another example, a grating is arranged on a bottom surface of the substrate support WT, and an encoder head is arranged below the substrate support WT.

The position measurement system PMS may comprise an interferometer system. An interferometer system is known from, for example, U.S. Pat. No. 6,020,964, filed on Jul. 13, 1998, hereby incorporated by reference. The interferometer system may comprise a beam splitter, a mirror, a reference mirror and a sensor. A beam of radiation is split by the beam splitter into a reference beam and a measurement beam. The measurement beam propagates to the mirror and is reflected by the mirror back to the beam splitter. The reference beam propagates to the reference mirror and is reflected by the reference mirror back to the beam splitter. At the beam splitter, the measurement beam and the reference beam are combined into a combined radiation beam. The combined radiation beam is incident on the sensor. The sensor determines a phase or a frequency of the combined radiation beam. The sensor generates a signal based on the phase or the frequency. The signal is representative of a displacement of the mirror. In an embodiment, the mirror is connected to the substrate support WT. The reference mirror may be connected to the metrology frame MF. In an embodiment, the measurement beam and the reference beam are combined into a combined radiation beam by an additional optical component instead of the beam splitter.

The first positioner PM may comprise a long-stroke module and a short-stroke module. The short-stroke module is arranged to move the mask support MT relative to the long-stroke module with a high accuracy over a small range of movement. The long-stroke module is arranged to move the short-stroke module relative to the projection system PS with a relatively low accuracy over a large range of movement. With the combination of the long-stroke module and the short-stroke module, the first positioner PM is able to move the mask support MT relative to the projection system PS with a high accuracy over a large range of movement. Similarly, the second positioner PW may comprise a long-stroke module and a short-stroke module. The short-stroke module is arranged to move the substrate support WT relative to the long-stroke module with a high accuracy over a small range of movement. The long-stroke module is arranged to move the short-stroke module relative to the projection system PS with a relatively low accuracy over a large range of movement. Such a long-stroke module can e.g. comprise a planar motor according to the present invention. With the combination of the long-stroke module and the short-stroke module, the second positioner PW is able to move the substrate support WT relative to the projection system PS with a high accuracy over a large range of movement.

The first positioner PM and the second positioner PW each are provided with an actuator to move respectively the mask support MT and the substrate support WT. The actuator may be a linear actuator to provide a driving force along a single axis, for example the y-axis. Multiple linear actuators may be applied to provide driving forces along multiple axis. The actuator may be a planar actuator to provide a driving force along multiple axis. For example, the planar actuator may be arranged to move the substrate support WT in 6 degrees of freedom. The actuator may be an electro-magnetic actuator comprising at least one coil and at least one magnet. The actuator is arranged to move the at least one coil relative to the at least one magnet by applying an electrical current to the at least one coil. The actuator may be a moving-magnet type actuator, which has the at least one magnet coupled to the substrate support WT respectively to the mask support MT. The actuator may be a moving-coil type actuator which has the at least one coil coupled to the substrate support WT respectively to the mask support MT. The actuator may be a voice-coil actuator, a reluctance actuator, a Lorentz-actuator or a piezo-actuator, or any other suitable actuator.

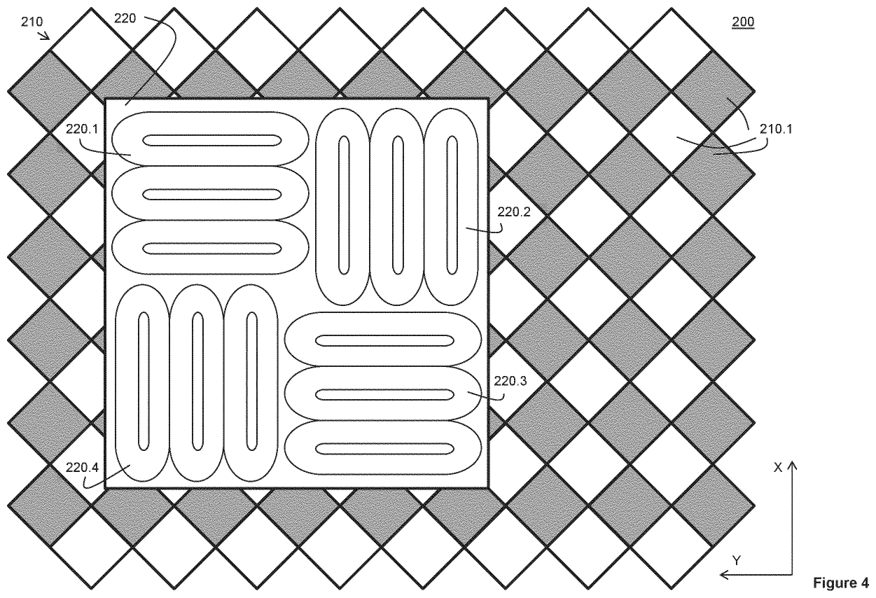

The lithographic apparatus LA comprises a position control system PCS as schematically depicted in FIG. 3. The position control system PCS comprises a setpoint generator SP, a feedforward controller FF and a feedback controller FB. The position control system PCS provides a drive signal to the actuator ACT. The actuator ACT may be the actuator of the first positioner PM or the second positioner PW. The actuator ACT drives the plant P, which may comprise the substrate support WT or the mask support MT. An output of the plant P is a position quantity such as position or velocity or acceleration. The position quantity is measured with the position measurement system PMS. The position measurement system PMS generates a signal, which is a position signal representative of the position quantity of the plant P. The setpoint generator SP generates a signal, which is a reference signal representative of a desired position quantity of the plant P. For example, the reference signal represents a desired trajectory of the substrate support WT. A difference between the reference signal and the position signal forms an input for the feedback controller FB. Based on the input, the feedback controller FB provides at least part of the drive signal for the actuator ACT.

The reference signal may form an input for the feedforward controller FF. Based on the input, the feedforward controller FF provides at least part of the drive signal for the actuator ACT. The feedforward FF may make use of information about dynamical characteristics of the plant P, such as mass, stiffness, resonance modes and eigenfrequencies.

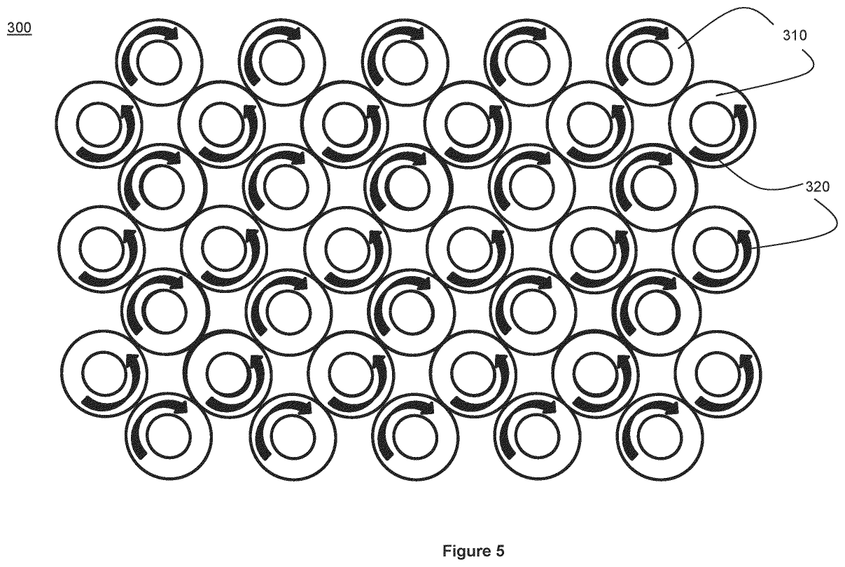

FIG. 4 schematically shows a top view of known planar motor 200 which can e.g. be used in a lithographic apparatus for the positioning of a substrate support such as substrate support WT discussed above. The planar motor 200 comprises a magnet assembly 210 comprising a plurality of permanent magnets 210.1 configured to generate a spatially alternating magnetic field in two directions; X-direction and Y-direction. The magnets as indicated by the grey squares have an opposite magnetic polarization compared to the magnets indicated by the white squares.

The planar motor 200 further comprises a mover 220, the mover having a coil assembly 220.1, 220.2, 220.3 and 220.4 configured to generate forces in both the X-direction and the Y-direction, by providing an appropriate current to the coils or coil sets 220.1, 220.2, 220.3 and 220.4 of the coil assembly. In the embodiment as shown, each coil set comprises a triplet of coils, which can e.g. be powered by a three-phase power supply. Note that the magnet assembly 210 of the planar motor 200 may also be referred to as the stator of the motor, although the magnet assembly 210 need not be configured to remain stationary. In particular, the magnet assembly 210 can be arranged as a balance mass.

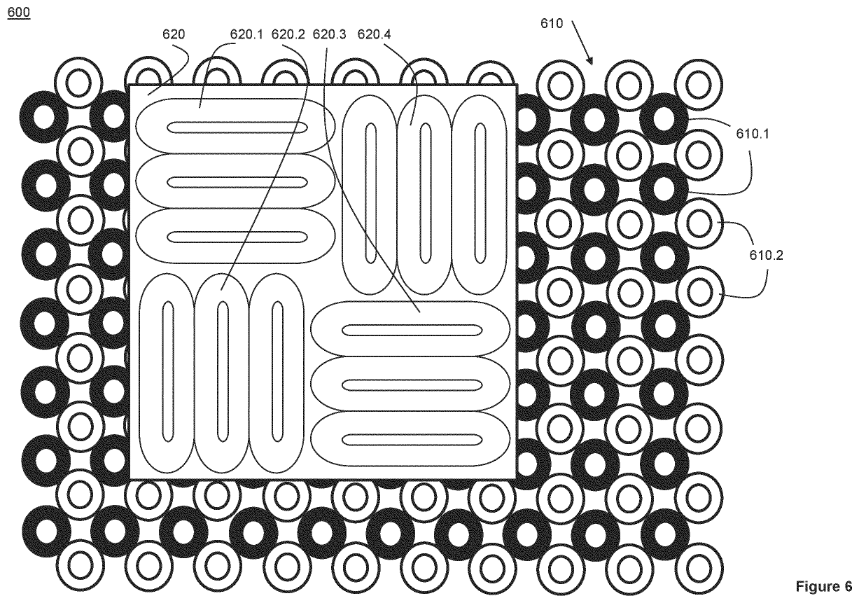

As an alternative to the use of permanent magnets for generating the magnetic field distribution required to operate a planar electromagnetic motor such as planar motor 200, it has been proposed to use superconductive (SC) coils. In such embodiment, circular or cylindrical coils may serve to generate a magnet field along an axial direction of the coils when the coils are supplied with a current. By suitable arrangement of the coils and the supply currents, one can obtain a magnet assembly that generates, in use, a two-dimensional spatially alternating magnetic field, similar to the magnetic field as generated by the magnet assembly 210 shown in FIG. 4. FIG. 5 schematically shows a top view of a two-dimensional (2D) array 300 of superconductive (SC) coils 310 which can generate, when powered, a two-dimensional spatially alternating magnetic field. The arrows 320 in the SC coils 310 are indicative for the direction of the current flowing in the SC coils 310.

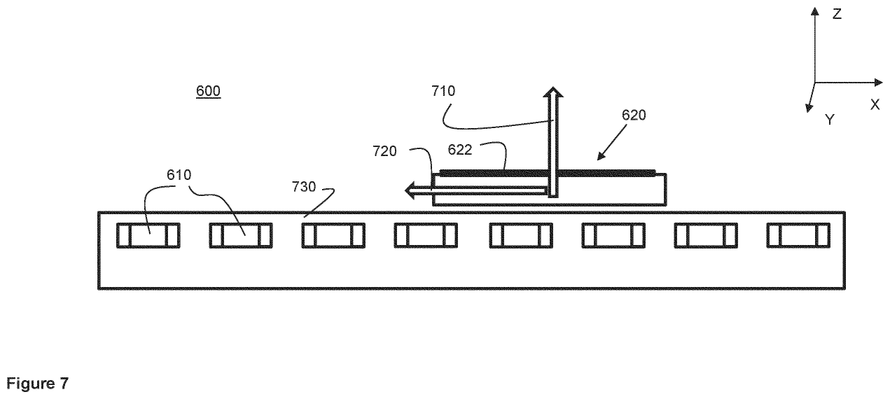

FIG. 6 schematically shows a top view of a planar motor 600 having, as a stator, an array of superconductive coils 610 configured to generate a two-dimensional spatially alternating magnetic field. In the arrangement as shown, the direction of the current in the black coils 610.1 is opposite to the direction of the current flowing in the white coils 610.2. By doing so, a two-dimensional spatially alternating magnetic field can be generated. The planar motor 600 further comprises a mover 620. In the arrangement as shown, the mover having a similar structure as the mover 220 shown in FIG. 4. In particular, the mover has a coil assembly comprising coils or coil sets 620.1, 620.2, 620.3 and 620.4 configured to generate forces in both the X-direction and the Y-direction, by providing an appropriate current to the coils or coil sets 620.1, 620.2, 620.3 and 620.4 of the coil assembly. It can also be pointed out that the set of currents as supplied to the coil sets can be configured to control a positioning of the mover relative to the array of superconductive coils 610 in six degrees of freedom.

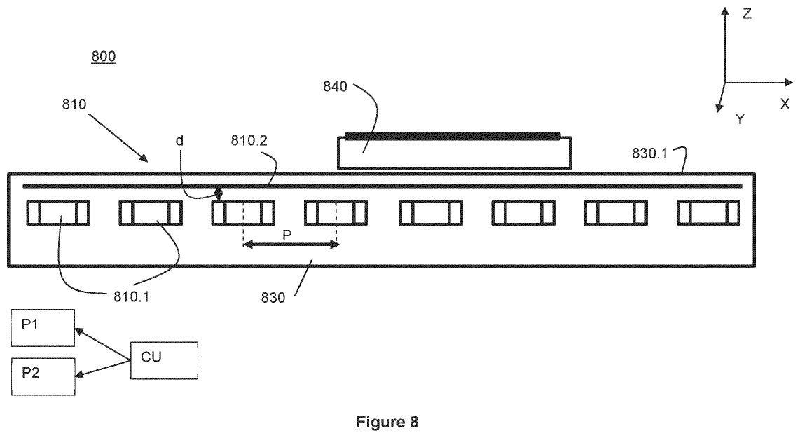

FIG. 7 schematically shows a cross-sectional side view of the planar motor 600 of FIG. 6. In FIG. 7, arrows 710 and 720 indicate force components of the force that is generated when the coils or coil sets of the mover 620 are supplied with suitable currents. In particular, the generated force may e.g. comprise a vertical component 710 to levitate the mover 620 relative to the stator 610, i.e. an array of superconductive coils 610, and a horizontal component 720 causing the mover 620 to displace relative to the stator 610 in the horizontal plane, i.e. the XY-plane. In the arrangement as shown, the 2D array of superconductive coils 610 is arranged in a cryostat 730 which is configured to maintain the superconductive coils 610 in a superconductive state.

When such a planar motor 600 would be applied in a lithographic apparatus, it is required to ensure that the magnetic field as generated by the 2D array of SC coils 610 is maintained, in order to realize an accurate positioning of the mover 620, said mover e.g. holding a substrate 622. It has been observed that the current carrying coils of the mover may induce losses in the superconductive coils of the 2D array of SC coils 610. Said losses can be considered to be caused by a magnetic field change as experienced by the 2D array of SC coils 610, whereby the magnetic field change can be attributed to the movement of the current carrying coils of the mover relative to the 2D array of SC coils 610 of the stator, or a current change or current transient in a coil of mover 620. Due to said losses, there is a risk of one or more coils, or even a part of a coil, of the 2D array of SC coils 610 undergoing a transition from a superconductive state to a normal conductive state. Such transition can also be referred to as a quench. In accordance with the present invention, measures are proposed to reduce or mitigate the risk of such a quench occurring during operation of the motor. In particular, in accordance with the present invention, it is proposed to arrange a shield that is configured to mitigate a magnetic field change as experienced by the 2D array of SC coils 610 during a displacement of a mover of the planar motor relative to the 2D array of SC coils 610.

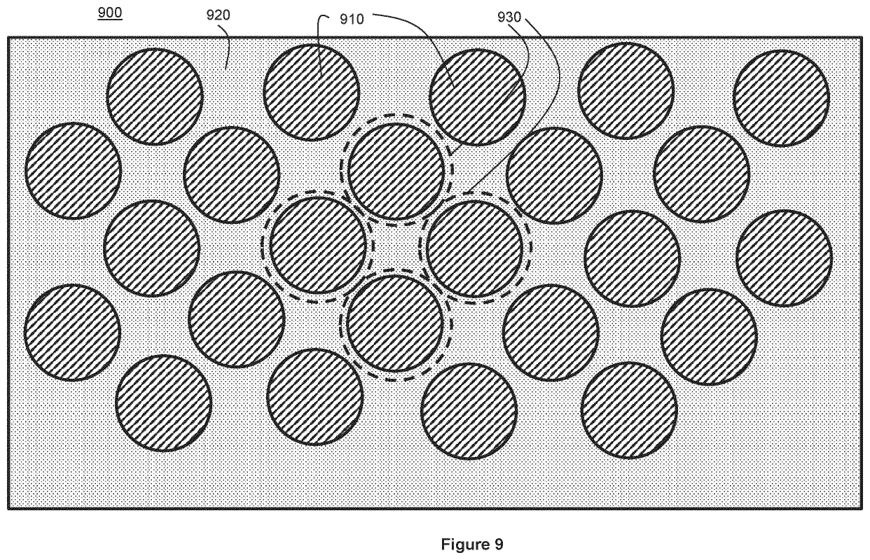

FIG. 8 schematically shows a cross-sectional view of a planar motor 800 according to the present invention, the planar motor comprising a magnet assembly 810 according to the present invention. In the embodiment as shown, the magnet assembly 810 comprises a 2D array of superconductive (SC) coils 810.1 and a shield 810.2. In the embodiment as shown, both the 2D array of SC coils 810.1 and the shield 810.2 are arranged in a cryostat 830. Depending on the material that is used as layer for the shield, it may also be possible to arrange the shield outside the cryostat, e.g. arranged on an outer surface of the cryostat. In an embodiment, the 2D array of SC coils 810.1 may be a two-dimensional array of circular or cylindrical coils as shown in FIGS. 5 and 6. In accordance with the present invention, the 2D array of SC coils 810.1 of the magnet assembly 810 is configured to generate a two-dimensionally spatially alternating magnetic field. Such magnetic field may be realised by supplying the 2D array of SC coils 810.1 of the magnet assembly with suitable currents, typically DC currents of several kAs. The magnetic field as generated will typically extend beyond the top surface 830.1 of the cryostat 830 and will have a magnitude that is superior to a magnetic field strength as generated using permanent magnets. In the embodiment as shown, the planar motor 800 further comprises a mover 840 configured to displace relative to the magnet assembly 810, e.g. in 6 degrees of freedom. In order to do so, the mover 840 may e.g. comprise one or more coil sets. When said coil sets are supplied with currents, a force will be generated due to the interaction between the currents as supplied to the coils of the mover and the magnetic field of the magnet assembly 810.

When the mover 840 moves relative to the magnet assembly 810, or when a current change or current transient occurs in one or more coils of the mover 620, the 2D array of SC coils 810.1 may experience a change in magnetic field strength. In the present invention, a shield 810.2 is applied to mitigate the adverse effects of such a magnetic field change. In accordance with the present invention, the shield 810.2 is arranged on a side of the 2D array of SC coils 810.1 which, during use, faces the mover 840 of the planar motor 800. In the embodiment as shown, the mover 840 is arranged above the magnet assembly 810. In such embodiment, the shield 810.2 may thus be arranged above the 2D array of SC coils 810.1, i.e. in between the 2D array of SC coils 810.1 and the mover 840. In the embodiment as shown, the shield substantially spans the entire area covered by the 2D array of SC coils 810.1. In an alternative embodiment the shield 810.2 may be arranged in between or below the 2D array of SC coils 810.1.

In accordance with the present invention, the shield comprises a layer of conductive material, whereby said layer substantially covers the area that is covered by the 2D array of SC coils 810.1 of the magnet assembly 810. In accordance with the present invention, the layer of conductive material further has a thickness variation across the area, the thickness variation being associated with a geometric parameter of the 2D array of SC coils.

In an embodiment, the layer of conductive material may be a layer of superconductive (SC) material.

When a shield according to the present invention is applied in a superconductive magnet assembly for a planar motor, adverse effects of magnetic field changes experienced by the array of SC coils can be mitigated. This can be understood as follows.

When the current carrying coils of the mover 840 cause a magnetic field change near the 2D array of SC coils 810.1, this magnetic field change will also be experienced by the layer of conductive material of the shield 810.2. In particular, the magnetic field change will induce a current or current distribution in the layer of conductive material, optionally a layer of SC material, of the shield 810.2. This current or current distribution will result in a magnetic field that opposes or counteracts the magnetic field change. As a result, the 2D array of SC coils 810.1 will experience a lower magnetic field change. As a result, less losses will be induced in the 2D array of SC coils, thus reducing the risk of a quench of one or more coils of the 2D array of SC coils. It can also be pointed out that due to the lower losses in the 2D array of SC coils, a lower temperature of the SC coils can be maintained and a lower cooling cost may be obtained. Due to this, the SC magnet assembly may be more robust as well.

By introducing a thickness variation in the layer of conductive material in the shield, an improved control of the induced magnetic field in the shield can be obtained.

In an embodiment, the planar motor 800 according to the present invention further comprises a first power source P1 for powering the 2D array of SC coils 810.1 and a second power source P2 for powering the one or more coil sets of the mover 840 of the planar motor 800. In an embodiment, the first power source P1 may e.g. be configured to supply DC currents to the 2D array of SC coils 810.1 of the magnet assembly 810 of the planar motor 800. The second power source P2 may e.g. be configured to provide sets of AC currents, e.g. three-phase currents, to the one or more coil sets of the mover 840 of the planar motor 800. The planar motor according to the present invention may further have a control unit CU for controlling the power sources P1 and P2.

Below, more details are provided on various embodiments of the shield as applied in the superconductive magnet assembly according to the invention, in particular on the applied thickness variation.

In an embodiment of the present invention, the thickness variation as applied to the layer of conductive material spans a thickness between a nominal thickness and zero. Phrased differently, the layer of conductive material needs not be a continuous layer of material spanning the area covered by the 2D array of SC coils 810.1. Rather, certain parts or portions of the shield may be without conductive material. Alternatively, certain areas or portions may be a layer of conductive material with a reduced or less than nominal thickness.

In an embodiment, the thickness variation of the layer of conductive material of the shield 810.2 comprises a repetitive pattern. Such a repetitive pattern may e.g. have a periodicity associated with a geometric parameter of the 2D array of SC coils 810.1. The periodicity may e.g. be associated with the pitch P of the 2D array of SC coils 810.1, the pitch P referring to the distance between adjacent coils in the 2D array of SC coils 810.1.

In an embodiment, the repetitive pattern comprises a repetitive pattern of geometric shapes, each geometric shape being associated with a SC coil of the 2D array of SC coils 810.1.

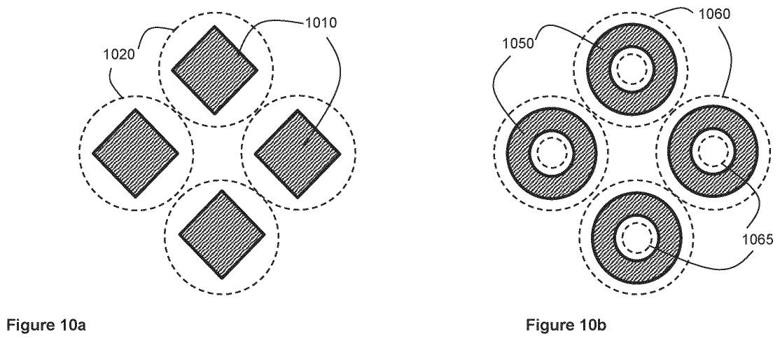

FIG. 9 schematically shows a patterned layer of conductive material as can be applied as a shield for a magnet assembly according to the present invention. In the embodiment as shown, the layer of conductive material 900 comprises a pattern of circles 910, each circle thus representing a circular shaped layer of conductive material. The area in between the circles 910, i.e. area 920 may either be covered with a layer of conductive material having a different thickness, or may be without conductive material. Note that, in an embodiment of the present invention, the layer of conductive material will be arranged on a supporting layer or surface. In case the layer of the conductive material is made from a metal such as Copper or Aluminium, the supporting layer or surface can e.g. be a plate made from a non-conductive material. In case the layer of conductive material is made from a superconductive material, the supporting layer can e.g. be a thin metal plate, e.g. an Aluminium or Copper plate. Note that such conductive plate may also be patterned, i.e. portions of the plate not covered by the superconductive material may at least partly be removed so as to reduce the conductivity between the areas of superconductive material, e.g. the pattern of circles 910.

Alternatively, the supporting layer or surface can also be made from a non-conductive material. In an embodiment of the present invention, a layer of SC material may be arranged on a layer or surface of the cryostat as the shield. As an example, a patterned layer of SC material may e.g. be arranged on the inner surface of a top plate of the cryostat, said top plate e.g. being arranged between the magnet assembly and the mover. Alternatively, or in addition, a patterned layer of conductive material, e.g.

Copper or Aluminium, may be arranged on an outer surface of the top plate of the cryostat. In the embodiment as shown, the dotted circles 930 represent the outer diameter of an SC coil of a 2D array of SC coils that is e.g. arranged underneath the shield or layer of conductive material 900 of the shield. So, in the arrangement as shown, the patterned layer of conductive material 900 comprises a plurality of circular shapes 910, whereby each shape can be associated with an SC coil of the 2D array of SC coils of the magnet assembly in which the shield is used. In the arrangement as shown, the circular shapes have a diameter that is somewhat smaller than the outer diameter of the associated SC coil. In the arrangement as shown, the circular shapes 910 are also aligned with the respective SC coils of the 2D array of SC coils of the magnet assembly to which the shield is applied.

As will be understood, the application of circular shapes 910 as a pattern in a layer of conductive material of a shield is merely one example of possible shapes and patterns which can be applied and which will enable a control of the magnetic field as induced in the shield due to a magnetic field change caused by a mover moving relative to the magnet assembly comprising the 2D array of SC coils, e.g. coils 810.1.

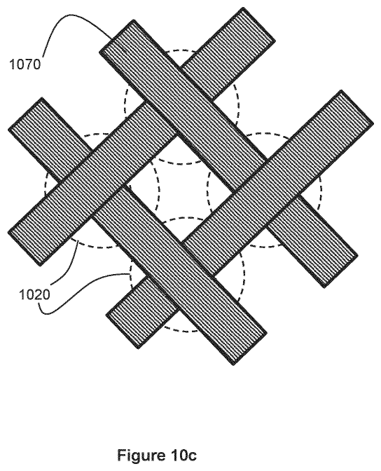

FIGS. 10a-10c schematically shows some further possible patterns of geometric shapes which can be applied to shape a layer of conductive material of a shield.

FIG. 10a schematically shows another example of a pattern that can be applied in a layer of conductive material for a shield as used in the present invention. The pattern comprises a plurality of squares 1010 which are configured to be aligned with a 2D array of SC coils. In FIG. 10 a, the dotted contours 1020 represent outer diameters of coils of such a 2D array of SC coils. In a similar manner as indicated above, the area outside the squares 1010 forming the pattern can be covered with conductive material having a different thickness then the squares 1010 or can be free of conductive material.

FIG. 10b schematically shows yet another example of a pattern that can be applied to a layer of conductive material for a shield as used in the present invention. The pattern comprises a plurality of ring shaped structures 1050 which are configured to be aligned with a 2D array of SC coils. In FIG. 10b the dotted contours 1060, 1065 represent outer and inner diameters of coils of such a 2D array of SC coils. In the arrangement as shown, the ring shaped structures 1050 have an outer diameter that is smaller than the outer diameter of the associated SC coil and an inner diameter that is larger than the inner diameter of the associated SC coil. Alternatives whereby the outer diameter of the ring shaped structures 1050 substantially corresponds to the outer diameter 1060 of the SC coil or whereby the inner diameter of the ring shaped structures 1050 is equal or smaller than the inner diameter 1065 of the SC coil can be considered as well.

FIG. 10c schematically shows yet another example of a pattern that can be applied to a layer of conductive material for a shield as used in the present invention. The pattern comprises a plurality of strips 1070 made from a conductive material, the strips being aligned with the pattern of the 2D array of SC coils of the magnet assembly. In FIG. 10c, the dotted contours 1020 represent outer diameters of coils of such a 2D array of SC coils. In the arrangement as shown, the strips are arranged in a woven manner. It can be pointed out that the strips needs not be arranged in a woven manner. Instead, two sets of parallel strips arranged on top of each other may be applied as well.

As mentioned, in accordance with the present invention, the layer of conductive material of the shield as applied in the magnet assembly has a thickness variation across the area that is associated with a geometric parameter of the 2D array of SC coils. As illustrated above, said geometric parameters of the 2D array of SC coils can include one or more of a pitch of the 2D array of SC coils or a geometric parameter of the coils themselves, such as an inner or an outer diameter of said SC coils.

In an embodiment, the thickness variation as applied to the layer of conductive material may also depend on the distance between the 2D array of SC coils and the shield, e.g. distance d as indicated in FIG. 8. The thickness variation may also depend on the applied distance between the coils of mover and the shield.

In an embodiment of the present invention, the SC magnet assembly comprises more than one shield. In an embodiment the SC magnet assembly comprises a plurality of shields, each shield having different pattern or thickness variation applied. Such an embodiment will offer even more design freedom in shaping the induced magnetic field that counteracts the magnetic field change.

The planar motor according to the present invention may advantageously be applied in a lithographic apparatus according to the invention. In particular, the planar motor may e.g. be applied as a second positioner PW as described above.

Although specific reference may be made in this text to the use of a lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Although specific reference may have been made above to the use of embodiments of the invention in the context of optical lithography, it will be appreciated that the invention, where the context allows, is not limited to optical lithography and may be used in other applications, for example imprint lithography.

Where the context allows, embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

1-19. (canceled)

20. A superconductive (SC) magnet assembly for a planar motor, the SC magnet assembly comprising:
a two-dimensional (2D) array of SC coils configured to generate a two-dimensional spatially alternating magnetic field; and
a shield arranged on a side of the 2D array of SC coils facing, during use, a mover of the planar motor, the shield being configured to mitigate a magnetic field change as experienced by the 2D array of SC coils, the shield comprising a layer of conductive material, the layer spanning an area substantially covering the 2D array of SC coils, the layer of conductive material having a thickness variation across the area, the thickness variation across the area being associated with a magnetic pitch of the array of SC coils, an inner diameter of a coil of the array of SC coils or an outer diameter of a coil of the array of SC coils of the 2D array of SC coils.

21. The SC magnet assembly of claim 20, wherein the magnetic field change is caused by a displacement of the mover of the planar motor relative to the 2D array of SC coils or by a current change or current transient in a coil or coil set of the mover.

22. The SC magnet assembly of claim 20, wherein the thickness variation spans a thickness between a nominal value and zero.

23. The SC magnet assembly of claim 20, wherein the thickness variation of the layer of conductive material comprises a repetitive pattern.

24. The SC magnet of claim 23, wherein the repetitive pattern comprises a repetitive pattern of geometric shapes, each geometric shape being associated with a SC coil of the array of SC coils.

25. The SC magnet assembly of claim 24, wherein the geometric shape comprises a circle or a square.

26. The SC magnet assembly of claim 20, wherein the layer of conductive material comprises a layer of SC material.

27. The SC magnet assembly of claim 20, wherein the layer of conductive material comprises a plurality of conductive or SC strips arranged in a woven pattern.

28. The SC magnet assembly of claim 20, wherein the layer of conductive material is arranged on a non-conductive layer or surface.

29. The SC magnet assembly of claim 20, wherein:
the layer of conductive material comprises a layer of SC material, and the layer of SC material is arranged on a non-conductive or conductive layer or surface.

30. The SC magnet assembly of claim 20, further comprising a cryostat, the 2D array of SC coils being arranged inside the cryostat.

31. The SC magnet assembly of claim 20, wherein the shield is arranged inside the cryostat.

32. The SC magnet assembly of claim 31, wherein the cryostat is configured to, during operation, to cool the 2D array of SC coils and the shield to a SC state.

33. The SC magnet of claim 31, wherein the shield is arranged on an inner surface or an outer surface of the cryostat that is arranged in between the 2D array of SC coils and the mover.

34. The SC magnet assembly of claim 31, wherein the shield is at least partly arranged in between the 2D array of SC coils.

35. A planar motor for use in a lithographic apparatus, the planar motor comprising:
the SC magnet assembly of claim 20; and
a mover comprising one or more coil sets configured to, during use, co-operate with a magnetic field of the 2D array of SC coils of the SC magnet assembly.

36. The planar motor of claim 35, further comprising:
a first power source configured to power the 2D array of SC coils, and
a second power source configured to power the one or more coil sets of the mover.

37. A lithographic apparatus comprising:
a planar motor comprising the SC magnet assembly of claim 20 and configured to position a substrate; and
a mover comprising one or more coil sets configured to, during use, co-operate with a magnetic field of the 2D array of SC coils of the SC magnet assembly.
